(19) United States
(12) Patent Application Publication
(10) Pub. No.: US 2005/0236267 A1
(43) Pub. Date: Oct. 27, 2005

(54) Methods and apparatus for controlling rotating magnetic fields

(76) Inventor: Paul Rich, Gloucestershire (GB)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/110,757

(22) Filed: Apr. 21, 2005

Related U.S. Application Data
(60) Provisional application No. 60/566,915, filed on May 3, 2004.

(30) Foreign Application Priority Data
Apr. 27, 2004 (GB) 0409337.3

(51) Int. Cl. C23C 14/35

(52) U.S. Cl. 204/192.13; 204/192.12; 204/298.03; 204/298.19; 204/298.2

(57) ABSTRACT

This invention relates to methods and apparatus for controlling a rotating magnetic field during processing of a substrate. A sputter target 10 is arranged symmetrically about an axis 11, about which rotates an offset magnetron 12. Magnetron 12 is controlled, relative to the proposed process, such that only complete magnetron rotations are used in the deposition process.

### CROSS REFERENCE TO RELATED APPLICATIONS

A claim of priority is made to U.S. provisional application Ser. No. 60/566,915 filed May 3, 2005 and British Patent Application No. 0409337.3 filed Apr. 27, 2004.

### BACKGROUND OF THE INVENTION

1. Field of the Invention

This invention relates to methods and apparatus for controlling a rotating magnetic field during a processing of a substrate.

2. Background of the Invention

In a number of processes, particularly in the field of semiconductor processing, it is desirable, in order to enhance uniformity, to have a rotating magnetic field. Such processes include film deposition and etching, but the approach is particularly well known in magnetron sputtering, where a rotating magnetic field is set up either by a rotating magnet or by appropriate switching around an array of field creating coils.

The use of such a system can provide substantially full faced target erosion, in a sputter deposition process, and this is particularly desirable as it in turn provides a clean deposition environment. It is well known that if any area of the target face receives re-deposition then it quickly becomes a particle source, particularly in reactive sputtering.

FIG. 1 illustrates, schematically, a typical prior art planar rotating magnetron arrangement wherein the magnets and related pole pieces are rotated about the centre of a target. Traditionally high rotational speeds are used in order to ensure good uniformity of deposition. This has worked well whilst deposition times have been the order of 20 seconds or greater and the rotation speeds have been greater than 100 rpm. This combination results in at least 33 magnetron rotations being performed per deposition. The arrangement provides good uniformity whether or not the number of rotations taking place during a particular process time is a whole number. For example if 33.5 complete rotations are performed during the deposition, the within wafer uniformity would still be good. Half a rotation does not provide a significant element of non-uniformity, as it is masked by the proceeding 33 complete turns. The effect is of the order of 1.5 per cent across the wafer.

However recent trends in the semiconductor industry have caused problems. Wafer diameters have increased from 200 mm to 300 mm with commensurate increases in target and magnetron sizes. The increased size of the magnetron has made it difficult to spin at such high speeds and the rotating magnets produce eddy currents within the target that oppose the magnetic field of the magnetron itself, with a resultant production of a force that opposes rotation. These issues become significant, because the rotation speed of the magnets at the edge will be about 1½ times faster for a 300 mm wafer as compared to a 200 mm one. There is also an increase in centrifugal force if the current rotational speeds are maintained. The Applicants have determined it is desirable to keep the rotational speed below 60 rpm.

At the same time the industry has moved to thinner films that require short process times of 15 seconds or less and which can be as low as 5 seconds. Often it is not desirable to increase these deposition times since the desired film property requires a high power applied to the target and increasing the source to substrate distance (to reduce sputtering efficiency) would likewise be undesirable for film properties. This is, for example, typically the case for self-ionised processes used for the deposition of barrier and seed layers.

The Applicants have appreciated that combining slower magnetron rotation speeds and shorter process times will mean that there will be fewer complete magnetron rotations per deposited film layer and any partial rotation is going to lead to much greater loss of uniformity, because it represents a much more significant percentage of the total number of rotations.

### SUMMARY OF THE INVENTION

The invention consists in a method of controlling a rotating magnetic field during processing of a substrate characterised in that at all times the whole substrate is exposed to the sputtering flux and in that the rotational speed of the magnetic field and the proposed process time are matched such that the field completes a whole number of rotations at the end of the process time.

In one embodiment the field has one or more pre-selected rotational speeds and the process time is equal to the period of a single rotation or multiples thereof.

Alternatively the process time may be fixed and an appropriate rotational speed may be calculated and operated.

In the first arrangement a parameter of the process may be adjusted to achieve the requisite process time, for example the applied power may be changed. However, significant changes in applied power may alter the nature of the film deposited and in general variations in the applied power should not exceed plus or minus ten per cent.

A computer may be used to calculate the appropriate method and it may operate using the hierarchy; process time, magnetic field rotational speed and applied power. An appropriate algorithm is described below.

As has been mentioned previously the rotating field may be provided by a rotating magnetron or by a fixed array of switched coils or indeed any other suitable arrangement.

The invention also includes apparatus for performing a process, over a process time, on the substrate including: a device for providing a rotating magnetic field and a control for ensuring the field completes a whole number of rotations at the end of the process time.

The control may be able to vary one or more of the power applied to the process, the process time or the speed of rotation of the magnetic field.

Although the invention has been described above it is to be understood it includes any inventive combination of the features set out above or in the following description.

### BRIEF DESCRIPTION OF THE DRAWINGS

The invention may be performed in various ways and embodiments will now be described, by way of example, with reference to the accompanying drawings in which:

FIG. 1 is a schematic view of a prior art rotating magnetron setup; and

FIG. 2 is a flow chart illustrating the decision process incorporated in embodiments of the invention.

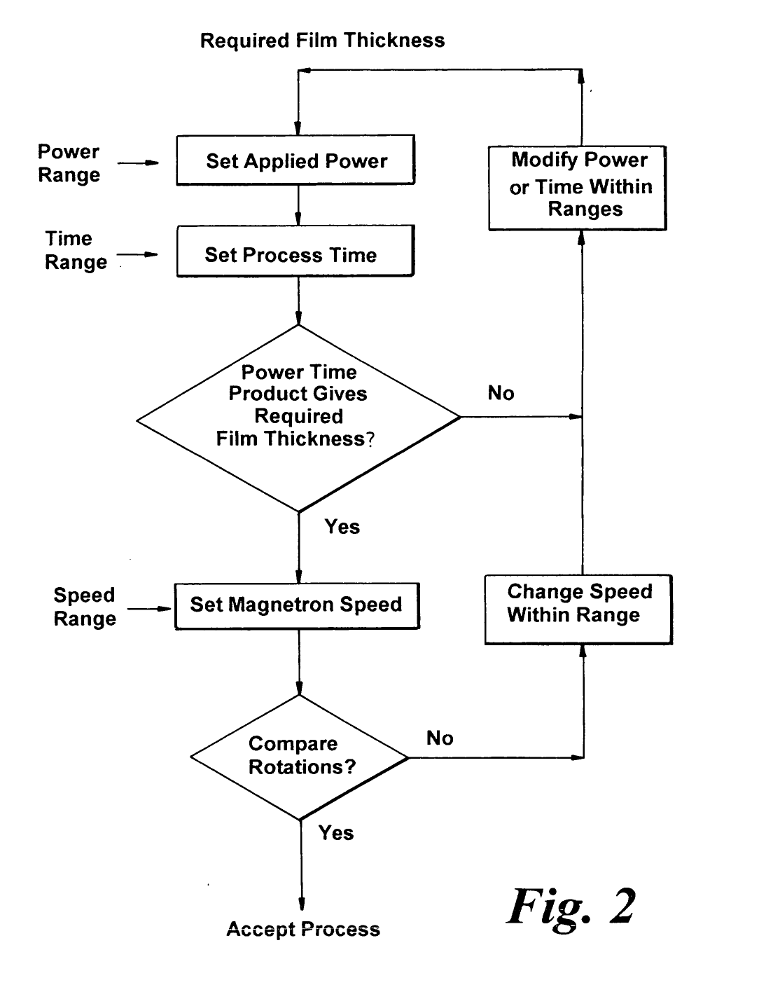

### DETAILED DESCRIPTION OF THE PREFERRED EMBODIMENTS

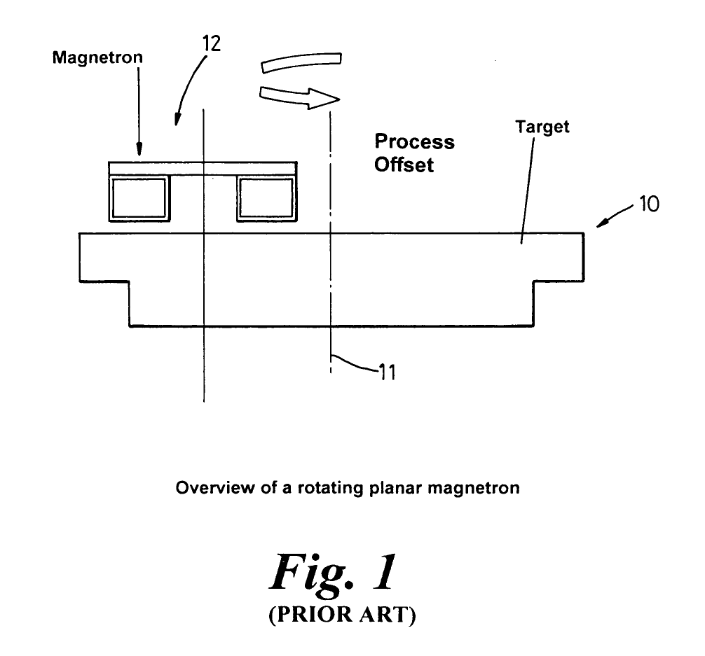

Thus in FIG. 1 a sputter target is indicated at 10. The target is symmetrically arranged about an axis 11, about which rotates an offset magnetron 12 for the purposes previously described.

Such apparatus, and indeed other appropriate deposition apparatus such as ones which use ion bombardment techniques, are well known in the art. In the Applicants proposal the apparatus includes a computer, either within the tool or external, which is provided to control the tool so that a complete number of magnetron rotations and no more occur during the process time required. The program may take into account desired film thickness, applied power and may calculate a process time and/or applied power and/or magnetron speed to ensure that only complete magnetron rotations are used in the deposition process.

By way of example, a magnetron speed of exactly 30 rpm might be used and combined with process times that are exactly 2 seconds or multiplies of 2 seconds. This combination ensures every deposition sequence consist only of complete rotations. It is understood that a different rotation speed could be chosen and when combined with a suitable process time the same effect could be achieved e.g. 15 rpm combined with process times of 4 seconds or multiples of 4 seconds.

Alternatively any process time could be programmed and a suitable rotation speed could be calculated by the machine. For example a 5 second process time could use a rotation speed of 24 rpm (this would give 2 complete rotations). Often a bi-layer of thin material, for example Ti and TiN, is deposited in a single chamber. The Ti may typically be 200 Å and TiN may typically be 500 Å thick. This results in the need for 2 short process times of 15 seconds or less. It may be impractical to change rotation speed quickly between different deposition steps and for this reason the fixed rotation speed method may be preferred especially for multi-step processes.

Less desirably the power could be varied. To optimise the process for complete magnetron rotations it may be useful to allow the power to be varied within the pre-programmed set points e.g. plus/minus ten per cent, but in general the applied power, e.g. the process rate is taken as unalterable as a significant change in process rate may have a material affect on film properties.

There may be a hierarchy of process time, magnetron set speed and applied power than can be arranged within the stored program such that an optimisation may be performed to ensure complete magnetron rotations within ranges of preferred time, speed and power particularly for multiple step processes.

No sensors are required to signal the position of the magnetron at any given time as the magnetron location is unimportant. All that is required to know is the magnetron's rotational speed and the commencement of the plasma.

In the prior art there are also problems associated with delayed plasma ignition. There is normally a delay between the application of power to the sputtering target and the plasma igniting. This delay is typically a few milliseconds but on occasions it can be of the order of several seconds. For this reason the Applicants' process timer only starts once the plasma has ignited (and deposition commenced) which can be either observed by a sensor or implied by the target current reaching a predetermined level. This is not at a known magnetron location, again obviating the need for a locations sensor.

Whilst this invention is principally directed to deposition processes where a target is eroded by a moving magnetron to deposit material upon a substrate, there are also other processes such as etching where the substrate is located in front of a moving magnetron and is the target for ionic bombardment.

Whilst this invention is principally directed to relatively large mechanically moving magnetic assemblies once can see that where a magnetic field is swept by non-mechanical means e.g. electrical switching and also where the magnetic sweeping is subsidiary process to an etching or deposition process e.g. a method of improving film properties then the invention may still be applied, that is the calculation and application of precise process time starting at plasma ignition to ensure complete magnetic sweeps or the calculation and application of complete magnetic sweeps for a given process time.

It should be understood that the rotation of the magnetic field in the apparatus of the invention is not to enable sputtered flux to reach the surface of the substrate—as might be the case for rotating magnetrons and three dimensional objects, but to achieve more complete target consumption and improved coating characteristics in a system where the substrate has a predominantly planar surface and is facing an opposing sputtering target.

1. A method of controlling a rotating magnetic field during processing of a substrate characterised in that at all times the whole substrate is exposed to the sputtering flux and in that the rotational speed of the magnetic field and the proposed process time are matched such that the field completes a whole number of rotations at the end of the process time.

2. A method as claimed in claim 1 wherein the process time is 15 seconds or less.

3. A method as claimed in claim 1 wherein the field has one or more pre-selected rotational speeds and the process time is equal to the period of a single rotation or multiples thereof.

4. A method as claimed in claim 1 wherein the process time is fixed and an appropriate rotational speed is calculated and operated.

5. A method as claimed in claim 3 wherein a parameter of the process is adjusted to achieve the requisite process time.

6. A method as claimed in claim 5 wherein the parameter is the applied power.

7. A method as claimed in claim 6 wherein the applied power is not varied by more than plus or minus ten percent.

8. A method as claimed in claim 1 wherein a computer is used to calculate parameters used to control the rotating magnetic field.

9. A method as claimed in claim 8 wherein the computer calculates parameters used to control the rotating magnetic field using the following hierarchy: process time, magnetic field rotational speed and applied power.

10. A method as claimed in claim 8 wherein the computer executes an algorithm comprising:
(a) choosing a desired film thickness;
(b) setting an applied power and a process time within respective predetermined power and time ranges;
(c) repeatedly modifying the applied power or process time within the predetermined ranges until a mathematical product of the applied power and the process time corresponds to the desired film thickness;
(d) setting a magnetron speed within a predetermined speed range according to the applied power and the process time; and,
(e) repeatedly modifying the magnetron speed within the predetermined speed range and executing (c) and (d) until the process time and the magnetron speed are such that a magnetic field rotating at the magnetron speed will undergo a whole number of rotations by the end of the process time.

11. A method as claimed in claim 1 wherein the rotation field is provided by a rotating magnetron or by a fixed array of switched coils.

12. Apparatus for performing a process, over a process time on a substrate including a device for providing a rotating magnetic field and a control for ensuring that the field completes a whole number of rotations at the end of the process time.

13. Apparatus as claimed in claim 12 wherein the control can vary one or more of the power applied to the process, the process time or the speed of rotation of the magnetic field.
